(19) United States
(12) Patent Application Publication
(10) Pub. No.: US 2009/0140285 A1
(43) Pub. Date: Jun. 4, 2009

(54) LIGHT EMITTING DEVICE HAVING FUNCTION OF HEAT-DISSIPATION AND MANUFACTURING PROCESS FOR SUCH DEVICE

(75) Inventors: Shun-Tian Lin, Taipei (TW); Wen-Hsiang Chien, Taipei (TW); Wen-Chin Lin, Taipei (TW); Jyun-Wei Huang, Taipei (TW); Sin-Sian Wu, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignees: ADVANCED CONNECTEK INC., Taipei (TW); TYSUN INC., Taipei County (TW)

(21) Appl. No.: 12/202,439

(22) Filed: Sep. 2, 2008

(30) Foreign Application Priority Data
Nov. 30, 2007 (TW) 96145693

(51) Int. Cl. H01L 33/00; H01L 21/00

(52) U.S. Cl. 257/100; 438/45; 257/E33.001; 257/E21.001

(57) ABSTRACT

A light-emitting device of a light-emitting diode (LED) and a manufacture method thereof are provided. The light-emitting device includes a post-like metal material, a printed circuit board, conductors, insulators, light-emitting diodes, wires, and an encapsulating material. The light-emitting device has through holes, in which conductors are disposed and surrounded with the insulators. One end of each conductor is connected to the printed circuit board to form a composite structure heat-dissipation substrate. The light-emitting diodes are disposed on the post-like metal material, connected to the conductors via the wires, and encapsulated by the encapsulating material. Furthermore, the light-emitting diodes, the wires, and the encapsulating material can be combined into a light-emitting unit. Moreover, red, blue, and green light-emitting diodes can be combined and the color of output light thereof can be adjusted by controlling the input signal.

### CROSS-REFERENCE TO RELATED APPLICATION

This application claims the priority benefit of Taiwan application serial no. 96145693, filed on Nov. 30, 2007. The entirety of the above-mentioned patent application is hereby incorporated by reference herein and made a part of specification.

### BACKGROUND OF THE INVENTION

1. Field of Invention

The present invention relates to a light-emitting device and manufacture method thereof. The light-emitting device integrates the functions of an electronic substrate and a heat-dissipation module to manage the thermal conducting and electrical conducting individually. Volume of the light-emitting device can be reduced and accordingly the application field of the same is wide. The light-emitting device can be further incorporated with the existing lamp holder to form a light bulb for illumination.

2. Description of Related Art

Light-emitting diode (LED) is characterized by long life time, high illumination, high illuminating efficiency, and low power consumption and has the potential to become the mainstream of the future illuminating light source instead of the conventional one due to its high reliability, short response time, and high color definition and color rendering index. However, the present LED light bulbs are usually fabricated by multiple-level-package with several packaging interfaces, which may cause thermal resistance, especially heat may accumulate on the printed circuit board and lead to a low heat-dissipation efficiency. Due to the insufficient heat-dissipation capability, the temperature of LED can not be effectively reduced, which results in low illuminating efficiency and short life time.

In addition, when the number of LED is increased for a higher illumination, the number of source electrodes is accordingly increased, which results in the aforementioned problem of lower heat-dissipation and gets troubles in arranging the electrodes and occupying more available area.

Moreover, one skilled in the art has electrically connected the LED to a heat-dissipation base material for a ground signal. The heat-dissipation base material is capable of heat-dissipating and grounding simultaneously. However, the heat-dissipation base material may contact with other conductors and make the circuitry short to damage the LED and reduce the yield factor. To prevent the above problem, the size and profile of the heat-dissipation base material shall be limited.

Furthermore, although the LED is gradually applied in illumination, it is not compatible with the present lamps yet. The problem of incompatibility not only limits the illuminating application of LED, but also requires a lot of cost to replace the incompatible lamps for LED, which is neither economical nor environmentally friendly.

### SUMMARY OF THE INVENTION

The main object of the present invention is to provide a composite structure and packaging method of a heat-dissipation module, wherein light-emitting diodes (especially LED chip die) are directly packaged on a post-like metal material in the form of “chip on heat-dissipation board”, to achieve high thermal conductivity and high stability to prevent heat accumulation in a printed circuit board and thus prolong the life time of light-emitting diodes.

Another object of the present invention is to provide a post-like metal material that can electrically connect the LED with the printed circuit board so as to decrease the overall area of the light-emitting device and increase its application range.

Another object of the present invention is to provide a light-emitting device, which can avoid the electrical short between the post-like metal material and other conductors, and thus improve the product yield.

Further another object of the present invention is to incorporate the light-emitting device with an existing lamp holder, wherein the light-emitting device can be directly adopted for illumination without replacing any present lamp equipment.

The manufacture method of the light-emitting device of the present invention includes: providing a post-like metal material having at least one through hole; providing at least one conductor surrounded with insulator in the through hole of the post-like metal material, wherein the conductor is post-like and two ends of the conductor are plated with metal by evaporation for being as electrodes; providing a printed circuit board having at least one electrode thereon, and electrically connecting one electrode at one end of the conductor to the electrode on the printed circuit board, such that the post-like metal material and the printed circuit board are incorporated into a composite heat-dissipation substrate having functions of thermal and electrical conduction; afterwards, providing and adhering a light-emitting diode to the post-like metal material; then, providing wires to electrically connect electrode of the light-emitting diode and the other electrode of the conductor through wire bonding, so as to form a complete electrical circuit for transmitting current; and finally, disposing phosphors and using an encapsulating material as a packaging material, to form the light-emitting device of the present invention.

In addition, concerning the method of integrating the post-like metal material, the conductor, and the insulator, the conductor can be encapsulated with the insulator first, and then the conductor and the insulator are inserted into the through hole of the post-like metal material as a whole. The second method is to dispose the conductor and the insulator separately into the through hole of the post-like metal material, wherein the insulator can be powdered and located between the conductor and the post-like metal material. Then, the conductor, the insulator, and the post-like metal material can be integrated together through a high-temperature sintering process. The third method is to providing a post-like metal material having a first surface and a second surface. Then, a ring groove is formed on the first surface forwarding the second surface. The conductor is formed by a part of the post-like metal material surrounded by the ring groove. Next, the insulator is filled into the ring groove and a high-temperature sintering process is conducted to combine the conductor, the insulator, and the post-like metal material together. Thereafter, the thickness of the post-like metal material is decreased by grinding, scraping, or digging the post-like metal material along the direction from the second surface to the first surface to expose the conductor and the insulator from the second surface.

It is to be understood that both the foregoing general description and the following detailed description are exemplary, and are intended to provide further explanation of the present invention as claimed.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, serve to explain the principles of the present invention.

FIG. 1 is a schematic diagram of the structure of a first embodiment of the present invention.

FIG. 2A is a schematic diagram of a post-like metal material and conductors encapsulated with insulators.

FIG. 2B shows a cross-sectional view of a conductor encapsulated with an insulator.

FIG. 3A is a schematic diagram of a printed circuit board and conductors encapsulated with insulators after being disposed on a post-like metal material.

FIG. 3B shows a cross-sectional view of a composite heat-dissipation substrate comprising a post-like metal material and a printed circuit board.

FIG. 3C is an enlarged diagram of the region I in FIG. 3B.

FIG. 4 shows a cross-sectional view of a composite heat-dissipation substrate after packaging with light-emitting diodes.

FIG. 5A is a schematic diagram of the structure of a second embodiment of the present invention, wherein light-emitting units are disposed on a composite heat-dissipation substrate.

FIG. 5B shows a cross-sectional view of one light-emitting unit from FIG. 5A.

FIG. 6 shows a cross-sectional view of a light-emitting device of the present invention incorporated with an existing lamp holder.

FIG. 7 is a partial side view showing the light-emitting device of the present invention incorporated with another existing lamp holder.

FIG. 8 shows the structure of FIG. 7 with a heat sink disposed at the outer side of the shade of the lamp holder.

FIG. 9A is a cross-sectional view of the post-like metal material with the ring groove.

FIG. 9B is a cross-sectional view illustrating filling the insulator into the ring groove of FIG. 9A.

FIG. 9C is a cross-sectional view of the post-like metal material of FIG. 9B after grinding, scraping, or digging the second surface thereof.

### DESCRIPTION OF THE EMBODIMENTS

Reference will now be made in detail to the present embodiments of the present invention, examples of which are illustrated in the accompanying drawings. The present invention is not restricted to the present embodiments, and can be realized in a wide variety of ways. Wherever possible, the same reference numbers are used in the drawings and the description to refer to the same or like parts. Different parts of elements in the figures are not drawn to scale; some dimensions have been exaggerated to give a clearer description and understanding of the present invention.

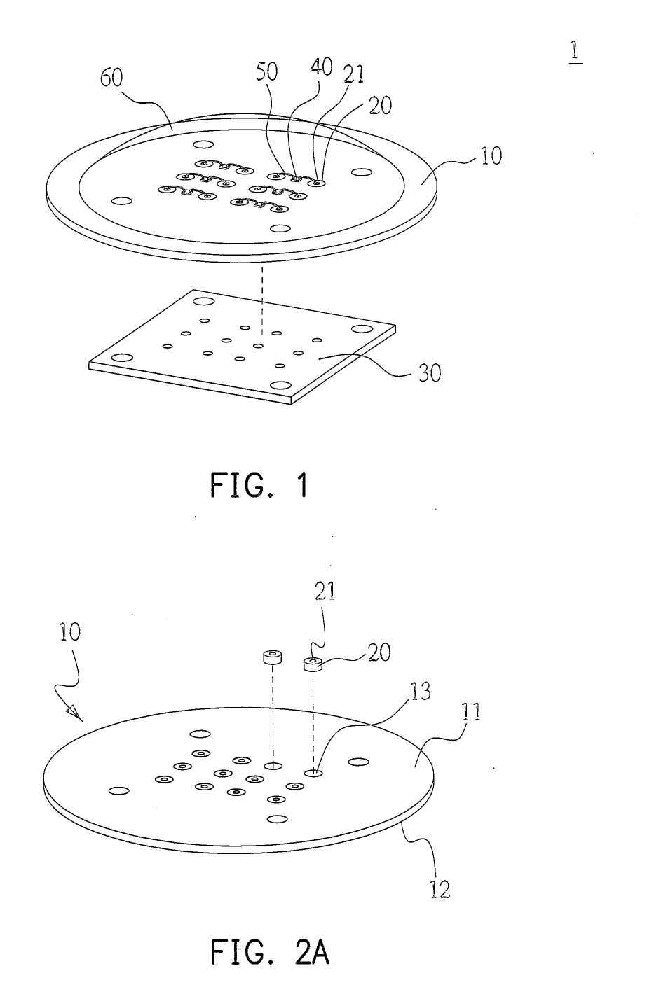

FIG. 1 is a schematic structure diagram of a first embodiment of the light-emitting device 1 of the present invention. The main structure of this light-emitting device 1 includes a post-like metal material 10, conductors 21, insulators 20 encapsulating the conductors 21, a printed circuit board 30, light-emitting diodes 40, wires 50, and an encapsulating material 60.

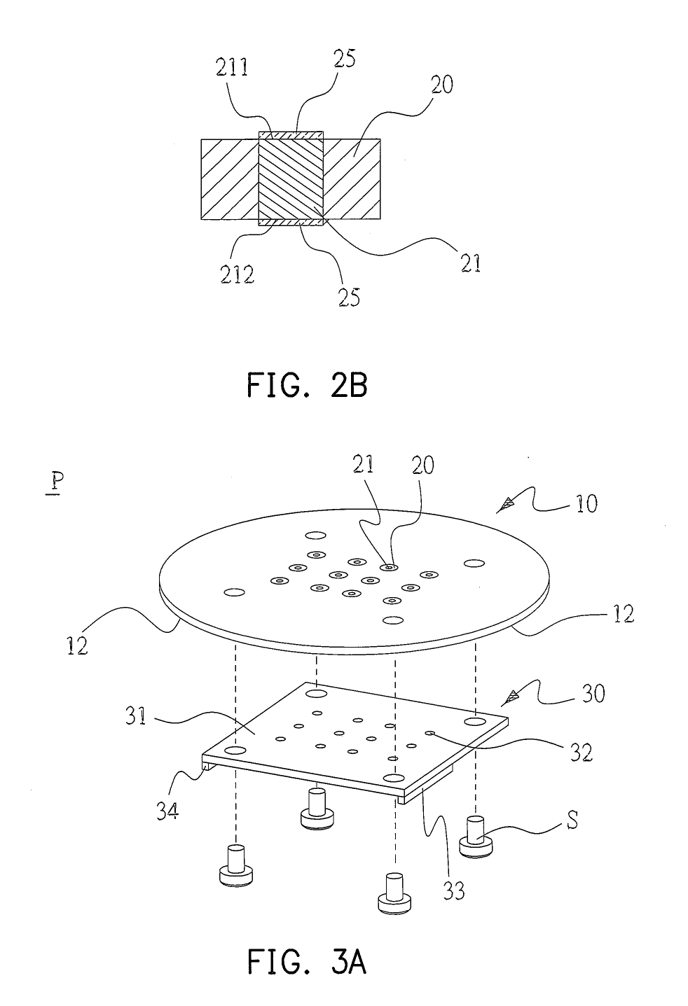

Please refer to FIGS. 2A and 2B. The post-like metal material 10 is metallic and post-like. For example, the post-like metal material 10 can be a cylinder or polygonal column. The first embodiment takes the cylindrical profile as an example. The post-like metal material 10 can be made of pure copper, copper alloy, pure aluminum, aluminum alloy, or a composite material of copper and aluminum. The post-like metal material 10 includes a first surface 11, a second surface 12, and a plurality of through holes 13 passing through the first surface 11 and the second surface 12. The conductors 21 are used to transmit electricity and are post-like. The conductors 21 are encapsulated by insulators 20. The top end 211 and the bottom end 212 of each conductor 21 are plated with a metal layer by evaporation, for being as the electrodes 25 to transmit electricity. The insulators 20 can be made of polymer material, ceramic material, or a composite material of the two. The metal layer plated at two ends of each conductor 21 by evaporation can be gold layer or silver layer. The conductors 21 and the insulators 20 encapsulating the same are disposed in the through holes 13 of the post-like metal material 10 and integrate as a whole, wherein the top end 211 of the conductor 21 is adjacent to the first surface 11 of the post-like metal material 10 and the bottom end 212 of the conductor 21 is adjacent to the second surface 12 of the post-like metal material 10.

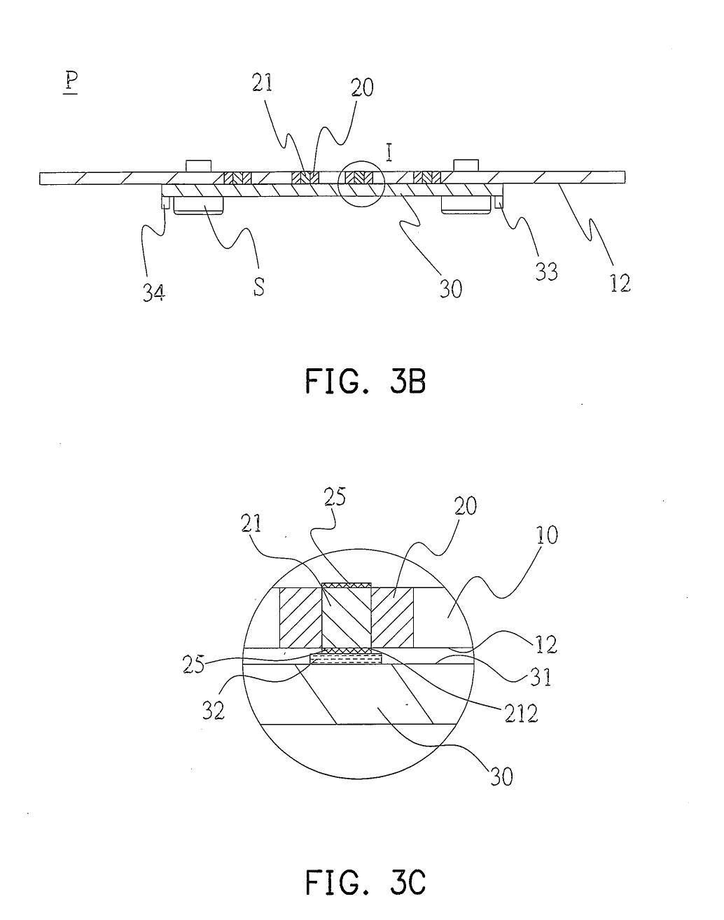

Please refer to FIGS. 3A, 3B, and 3C. The post-like metal material 10, the conductors 21 encapsulated by the insulators 20, and the printed circuit board 30 form a composite heat-dissipation substrate P. The printed circuit board 30 includes a top surface 31, a plurality of electrodes 32 disposed on the top surface 31, and a first input electrode 33 and a second input electrode 34. Some of the electrodes 32 are electrically connected to the first input electrode 33, and the others are electrically connected to the second input electrode 34, so that external electrical signal can be transmitted to the electrodes 32 through the first input electrode 33 and the second input electrode 34. The second surface 12 of the post-like metal material 10 faces the top surface 31 of the printed circuit board 30, such as the electrode 25 on the bottom end 212 of each conductor 21 is electrically connected to the corresponding electrode 32 on the top surface 31 of the printed circuit board 30. The post-like metal material 10 can be bonded to the printed circuit board 30 by screwing, gluing with resin, or soldering with solder tin between the electrode 25 on the bottom end 212 of each conductor 21 and the corresponding electrode 32 on the top surface 31, to form the composite heat-dissipation substrate P. Referring to FIG. 3B, the present embodiment uses screws S to screw the post-like metal material 10 and the printed circuit board 30 together to form the composite heat-dissipation substrate P. The first input electrode 33 and the second input electrode 34 are disposed on two opposite sides of the top surface 31 for consequential circuit installations.

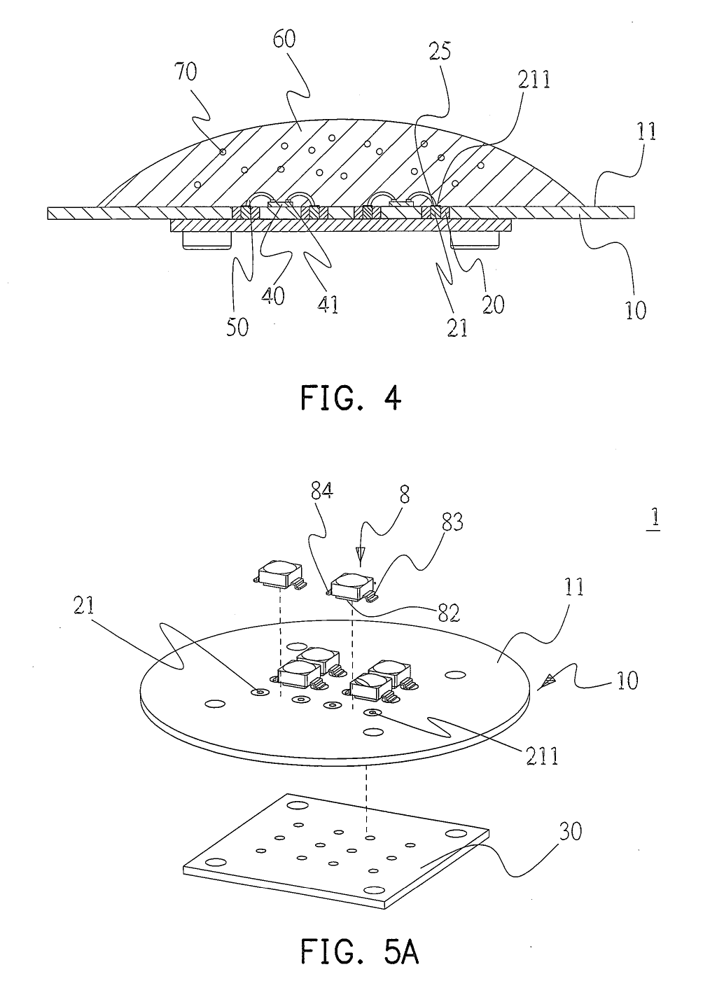

Please refer to FIG. 4. Each light-emitting diode 40 includes electrodes 41 disposed at one side of the light-emitting diode 40. The other side of the light-emitting diode 40 without electrodes 41 is attached to the first surface 11 of the post-like metal material 10 adhering with tin paste, conductive silver glue, or soldering tin. The light-emitting diode 40 can be an LED chip die or a light-emitting unit 8 which is illustrated in the following paragraph. Then, wires 50 are used to connect the electrodes 41 of the light-emitting diodes 40 with the electrodes 25 on the top ends 211 of the conductors 21, so as to form a complete electrical circuit. In this embodiment, each light-emitting diode 40 is collocated with two conductors 21, wherein one of the conductors provides an electrical signal, and the other provides a ground signal, so as to form a complete electrical circuit. In another case, one conductor 21 can provide a ground signal to plural light-emitting diodes 40, wherein the light-emitting diodes 40 are connected in parallel. In further another case, one conductor 21 can provide an electrical signal to plural light-emitting diodes 40, wherein the light-emitting diodes 40 are connected in parallel.

In order to avoid oxidation of the wires 50 in the atmosphere, encapsulating material 60 can be used as a packaging material. The encapsulating material 60 can be silicon rubber, and the packaging area shall include the first surface 11 of the post-like metal material 10 and covers at least the electrode 25 on the top end 211 of each conductor 21, the light-emitting diodes 40, and the wires 50, so as to isolate the aforementioned devices from the atmosphere, to form the light-emitting device 1 of the present invention. Furthermore, phosphors 70 can be disposed around the light-emitting diodes 40 so as to change the color of the light emitted by the light-emitting diodes 40. Hence, the addition of phosphors 70 is optional. The phosphors 70 can be disposed individually before packaging or be doped into and mixed with the encapsulating material 60 for packaging.

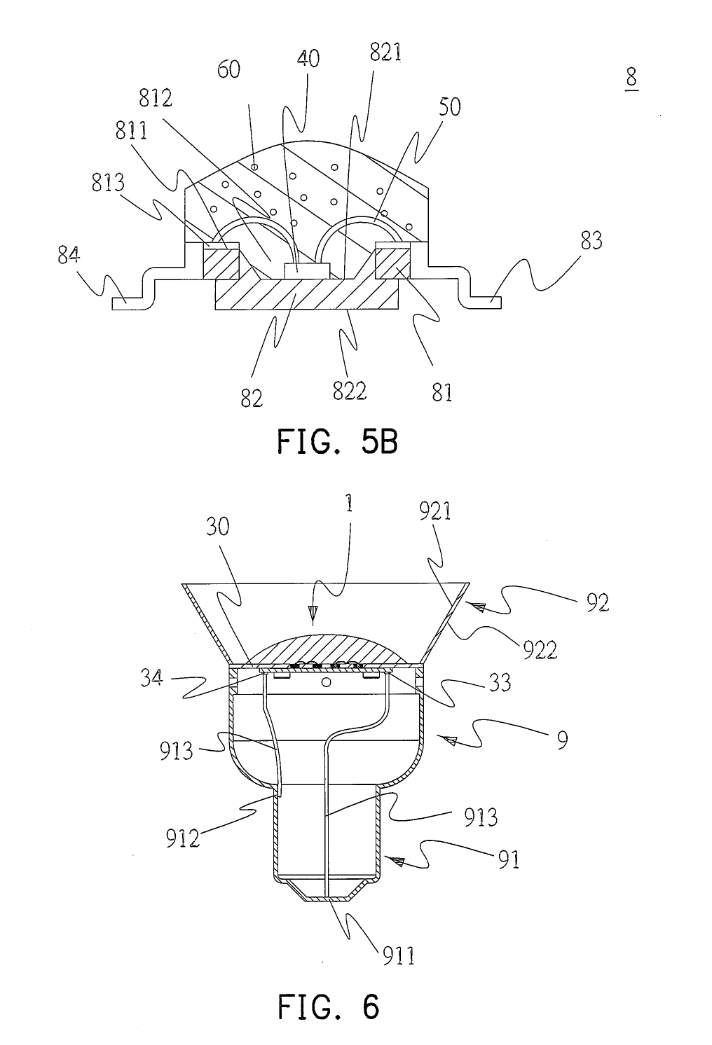

Referring to FIG. 5A illustrating a second embodiment of the present invention, other than the above mentioned manner of disposing the light-emitting diodes 40 and the wires 50, the light-emitting diodes 40 and the wires 50 can further be packaged into a light-emitting unit 8 first, and then be directly soldered or adhered on to the first surface 11 of the post-like metal material 10 of the composite heat-dissipation substrate P. Please refer to FIG. 5B. Each light-emitting unit 8 includes a substrate 81, a heat-dissipation base 82, at least one light-emitting diode 40, a plurality of wires 50, two electrode terminals 83, 84, and encapsulating material 60. The substrate 81 is an insulator, including a first surface 811, a through hole 812, and an electrical circuit 813 disposed on the first surface 811. The heat-dissipation base 82 is post-like and disposed in the through hole 812 of the substrate 81, wherein the heat-dissipation base 82 includes a top surface 821 and a bottom surface 822. The light-emitting diode 40 is adhered to the top surface 821 of the heat-dissipation base 82, and connected to the electrical circuit 813 on the substrate 81 via wires 50. The electrode terminals 83 and 84 are connected to the electrical circuit 813 on the substrate 81 respectively, for inputting electrical signals. The encapsulating material 60 encapsulates the first surface 811 of the substrate 81. In addition, different combinations of red, blue, and green light-emitting diodes 40 in a fixed quantity can be selected and attached to the top surface 821 of the heat-dissipation base 82, wherein the color of the light-emitting unit 8 can be adjusted by controlling the input electrical signal.

Please refer to FIG. 5A. The light-emitting unit 8 is attached to the first surface 11 of the post-like metal material 10. The bottom surface 822 of the heat-dissipation base 82 is attached to the first surface 11 of the post-like metal material 10, to transmit heat generated by the light-emitting diodes 40 away. The electrode terminals 83, 84 of each light-emitting unit 8 are electrically connected to the top surface 211 of the corresponding conductor 21, to form a light-emitting device 1.

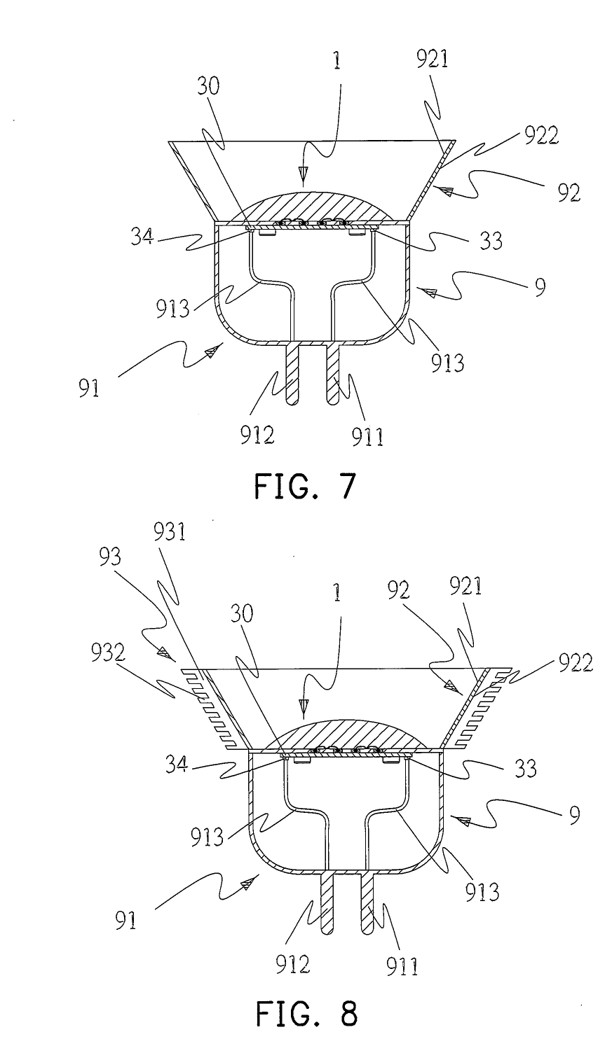

Please refer to FIGS. 6 and 7. The light-emitting device 1 can be mounted on an existing lamp holder 9, and serve as a light bulb for illumination.

The lamp holder 9 includes a stand 91 being metallic and tube-like, and a shade 92 being cup-like and disposed beside the stand 91, wherein the shade 92 includes an inner side 921 and an outer side 922. The light-emitting device 1 is disposed at the inner side of the shade 92. The shade 92 is an insulator made of ceramic materials or polymer, or can be metallic. The inner side 921 of the shade 92 can be plated with metal such as aluminum, nickel, or silver to form a reflective layer, so as to converge and amplify the output light of the light-emitting device 1. The first electrical signal input 911 and the second electrical signal input 912 on the stand 91 are electrically connected to the first and second input electrodes 33, 34 on the printed circuit board 30 of the light-emitting device 1 through conducting wires 913, respectively, so as to provide electrical signals to the light-emitting device 1, and then the light-emitting device 1 emits light.

Please refer to FIG. 8. Heat sinks 93 may be attached to the outer side 922 of the shade 92 of the lamp holder 9. The heat sinks 93 include a main body 931 and a plurality of fins 932, wherein the fins 932 are parallel and isolated from each other and are perpendicularly connected to the main body 931, to enhance the heat-dissipation capability of the lamp holder 9.

The manufacture method of a light-emitting device 1 of a LED in the present invention includes the following steps: providing a post-like metal material 10, which includes a first surface 11, a second surface 12, and a plurality of through holes 13 passing through the first surface 11 and second surface 12; providing a plurality of conductors 21 encapsulated by insulators 20 and disposed in the through holes 13 of the post-like metal material 10, wherein the conductors 21 are post-like; providing a printed circuit board 30, wherein the printed circuit board 30 includes a top surface 31 and a plurality of electrodes 32 disposed on the top surface 31; facing the second surface 12 of the post-like metal material 10 to the top surface 31 of the printed circuit board 30, and electrically connecting one end of each conductor 21 to the corresponding electrode 32; providing at least one light-emitting diode 40 with electrodes 41, and attaching the light-emitting diodes 40 on the first surface 11 of the post-like metal material 10; providing a plurality of wires 50, wherein one end of each wire 50 is electrically connected to the electrode 41 of the corresponding light-emitting diode 40, and the other end of the wire 50 is electrically connected the end of the corresponding conductor 21 that is not connected to the electrode 32 of the printed circuit board 30; providing an encapsulating material 60 for packaging. The encapsulating material 60 mainly encapsulates the first surface 11 of the post-like metal material 10, and shall covers at least the top end 211 of each conductor 21, the light-emitting diodes 40, and the wires 50. Phosphors 70 can also be disposed around the light-emitting diodes 40 or doped into the encapsulating material 60.

In addition, concerning the method of integrating the post-like metal material 10, the conductors 21, and the insulators 20, the conductors 21 can be encapsulated with the insulators 20 first, and then the conductors 21 and the insulators 20 are inserted into the through holes 13 of the post-like metal material 10 as a whole. The second method is to dispose the conductors 21 and the insulators 20 separately into the through holes 13 of the post-like metal material 10, wherein the insulators 20 can be powdered and located between the conductors 21 and the post-like metal material 10. Then, the conductors 21, the insulators 22, and the post-like metal material 10 can be combined together through a high-temperature sintering process.

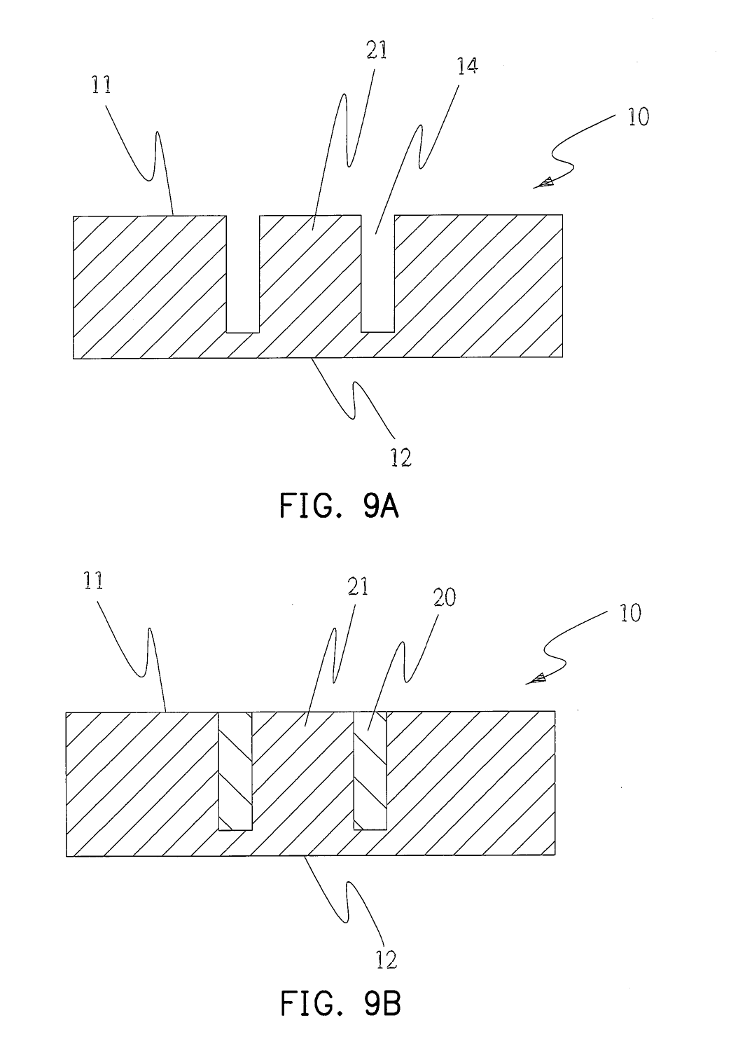

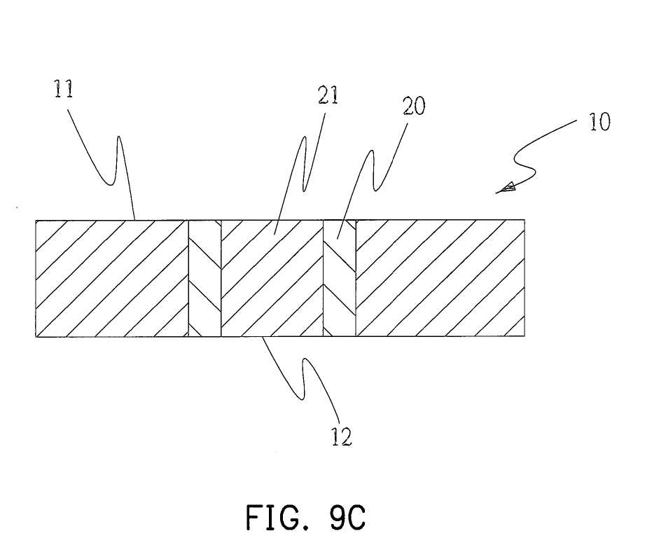

Please refer to FIGS. 9A-9C. A third method of combining the post-like metal material 10, the conductor 21, and the insulator 20 is illustrated. First, a post-like metal material 10 having a first surface 11 and a second surface 12 is provided. Then, a ring groove 14 is formed on the first surface 11 forwarding the second surface 12. The conductor 21 is formed in the center of the ring groove 14. Next, the insulator 20 is filled into the ring groove 14 and a high-temperature sintering process is conducted to combine the conductor 21, the insulator 20, and the post-like metal material 10 together. Thereafter, the thickness of the post-like metal material 10 is decreased by grinding, scraping, or digging the post-like metal material 10 in the direction from the second surface 12 to the first surface 11 to expose the conductor 21 and the insulator 20 from the second surface 12.

As stated above, the present invention packages the light-emitting diode 40 directly on the post-like metal material 10 to achieve a design of light-emitting device 1 with high heat-dissipating efficiency and high stability.

In addition, the electrodes 32 of the printed circuit board 30 is located below the post-like metal material 10, such that the electrode 41 of each light-emitting diode 40 can be electrically connected to the corresponding electrode 32 on the printed circuit board 30 via the corresponding conductor 21 in the post-like metal material 10, so as to decrease the overall area of the light-emitting device 1 and increase its application range.

Moreover, each light emitting device 40 of the light-emitting device 1 is collocated with two conductors 21, wherein one of the conductors 21 transmits an electrical signal, and the other transmits a ground signal. In other words, the ground signal is not transmitted by the post-like metal material 10. Therefore, thus the electrical short between the post-like metal material 10 and other conductors can be prevented.

Furthermore, the light-emitting device 1 can be incorporated with an existing lamp holder 9, wherein the light-emitting device 1 of LED can be directly adopted for illumination without replacing any present lamp.

It will be apparent to those skilled in the art that various modifications and variations can be made to the structure of the present invention without departing from the scope or spirit of the present invention. In view of the foregoing descriptions, it is intended that the present invention covers modifications and variations of this invention if they fall within the scope of the following claims and their equivalents.

What is claimed is:

1. A light-emitting device, comprising:
a post-like metal material having a first surface and a second surface, and provided with a plurality of through holes communicating the first surface and the second surface;
a plurality of conductors, each disposed in the through hole respectively;
a plurality of insulators, each disposed in the through hole respectively and insulating the corresponding conductor from the post-like metal material;
a printed circuit board having a top surface and a plurality of electrodes disposed on the top surface, the top surface facing the second surface of the post-like metal material;
at least one light-emitting diode disposed on the first surface of the post-like metal material and having electrodes;
a plurality of wires, one end of each wire being electrically connected to the corresponding electrode of the light-emitting diode; and
an encapsulating material, covering the first surface of the post-like metal material,
wherein one end of each conductor is electrically connected with the corresponding electrode of the printed circuit board and the other end of each conductor is electrically connected with the corresponding wire.

2. The light-emitting device according to claim 1, wherein material of the post-like metal material is selected from a group consisting of pure copper, copper alloy, pure aluminum, aluminum alloy, a composite material of copper and aluminum and a combination thereof.

3. The light-emitting device according to claim 1, wherein two ends of each conductor are plated with gold or silver.

4. The light-emitting device according to claim 1, wherein material of the insulators is selected from a group consisting of polymer material, ceramic material, a composite material of the two and a combination thereof.

5. The light-emitting device according to claim 1, wherein the post-like metal material and the printed circuit board are bonded together by screwing, gluing with resin, or soldering with soldering tin.

6. The light-emitting device according to claim 1, further comprising phosphors disposed around the light-emitting diodes.

7. The light-emitting device according to claim 1, further comprising phosphors doped into the encapsulating material.

8. The light-emitting device according to claim 1, wherein the light-emitting diodes are attached on the post-like metal material by solder paste, conductive silver glue, or soldering tin.

9. The light-emitting device according to claim 1, further comprising a lamp holder including a metallic tube-like stand and a cup-like shade disposed at one end of the stand, the shade having an inner side and an outer side, the light-emitting diode being installed at the inner side of the shade.

10. The light-emitting device according to claim 9, wherein an inner wall of the shade is plated with aluminum, nickel, or silver to form a reflective layer.

11. The light-emitting device according to claim 9, further comprising a heat sink disposed at the outer side of the shade, the heat sink including a main body and a plurality of fins, the fins being parallel and isolated from each other and being perpendicularly connected to the main body.

12. A light-emitting device, comprising:
a post-like metal material, having a first surface and a second surface, and provided with a plurality of through holes communicating the first surface and second surface;
a plurality of conductors, each disposed in the through hole respectively;
a plurality of insulators, each disposed in the through hole respectively and insulating the corresponding conductor from the post-like metal material;
a printed circuit board having a top surface and a plurality of electrodes disposed on the top surface, the top surface facing the second surface of the post-like metal material; and
at least one light-emitting unit disposed on the first surface of the post-like metal material, the light-emitting unit including:
a substrate being an insulator and having a first surface, a through hole and an electrical circuit on the first surface;
a post-like heat-dissipation base disposed in the through hole of the substrate, and having a top surface and a bottom surface attached to the first surface of the post-like metal material;
at least one light-emitting diode attached to the top surface of the heat-dissipation base;
a plurality of wires electrically connecting the light-emitting diode to the electrical circuit on the substrate;
two electrode terminals, one end of each electrode terminal being connected to the electrical circuit on the substrate, wherein one end of each conductor is electrically connected with the corresponding electrode of the printed circuit board and the other end of each conductor is electrically connected with the corresponding electrode terminal; and
an encapsulating material covering the first surface of the substrate.

13. The light-emitting device according to claim 12, wherein material of the post-like metal material is selected from a group consisting of pure copper, copper alloy, pure aluminum, aluminum alloy, a composite material of copper and aluminum and a combination thereof.

14. The light-emitting device according to claim 12, wherein the two ends of each conductor are plated with gold or silver.

15. The light-emitting device according to claim 12, wherein material of the insulators is selected from a group consisting of polymer material, ceramic material, a composite material of the two and a combination thereof.

16. The light-emitting device according to claim 12, wherein the post-like metal material and the printed circuit board are bonded together by screwing, gluing with resin, or soldering with soldering tin.

17. The light-emitting device according to claim 12, further comprising phosphors disposed around the light-emitting diodes.

18. The light-emitting device according to claim 12, further comprising phosphors doped into the encapsulating material.

19. The light-emitting device according to claim 12, wherein the light-emitting diodes are attached on the post-like metal material by solder paste, conductive silver glue, or soldering tin.

20. The light-emitting device according to claim 12, further comprising a lamp holder including a metallic tube-like stand and a cup-like shade disposed at one end of the stand, the shade having an inner side and an outer side, the light-emitting unit being installed at the inner side of the shade.

21. The light-emitting device according to claim 20, wherein an inner wall of the shade is plated with aluminum, nickel, or silver to form a reflective layer.

22. The light-emitting device according to claim 20, further comprising a heat-sink disposed at the outer side of the shade, the heat-sink including a main body and a plurality of fins, the fins being parallel and isolated from each other and being perpendicularly connected to the main body.

23. A manufacturing method of a light-emitting device, the manufacturing method comprising:
providing a post-like metal material having a first surface and a second surface, and provided with a plurality of through holes communicating the first surface and the second surface;
providing a plurality of post-like conductors, each surrounded with an insulator and disposed in the through hole respectively;
providing a printed circuit board having a top surface and a plurality of electrodes disposed on the top surface;
facing the second surface of the post-like metal material to the top surface of the printed circuit board, and electrically connecting one end of each conductor to the corresponding electrode;
providing at least one light-emitting diode including electrodes, and attaching the light-emitting diode to the post-like metal material;
providing a plurality of wires, wherein one end of each wire is electrically connected to the corresponding electrode of the light-emitting diode, and the other end of each conductor is electrically connected with the corresponding wire; and
providing an encapsulating material for covering the first surface of the post-like metal material.

24. The manufacturing method according to claim 23, further comprising providing phosphors around the light-emitting diodes or doping phosphors into the encapsulating material.

25. A manufacturing method of a light-emitting device, the manufacturing method comprising:
providing a post-like metal material having a first surface and a second surface, and provided with a plurality of through holes communicating the first surface and the second surface;
providing a plurality of post-like conductors, each disposed in the through hole respectively;
providing a plurality of insulators, each disposed in the through hole respectively and insulating the corresponding conductor from the post-like metal material;
performing a high-temperature sintering process to integrate the conductors, the insulators, and the post-like metal material as a whole;
providing a printed circuit board having a top surface and a plurality of electrodes disposed on the top surface;
facing the second surface of the post-like metal material to the top surface of the printed circuit board, and electrically connecting one end of each conductor to the corresponding electrode;
providing at least one light-emitting diode including electrodes, and attaching the light-emitting diode to the post-like metal material;
providing a plurality of wires, wherein one end of each wire is electrically connected to the corresponding electrode of the light-emitting diode, and the other end of each conductor is electrically connected with the corresponding wire; and
providing an encapsulating material for covering the first surface of the post-like metal material.

26. The manufacturing method according to claim 25, further comprising providing phosphors around the light-emitting diodes or doping phosphors into the encapsulating material.

27. A manufacturing method of a light-emitting device, the manufacturing method comprising:
providing a post-like metal material having a first surface and a second surface, and provided with a ring groove on the first surface, a part of the post-like metal material surrounded by the ring groove forming a conductor;
providing an insulator to fill the ring groove;
performing a high-temperature sintering process to integrate the conductor, the insulator, and the post-like metal material as a whole;
decreasing the thickness of the post-like metal material by grinding, scraping, or digging the post-like metal material along the direction from the second surface to the first surface to expose the conductor and the insulator from the second surface;
providing a printed circuit board having a top surface and a plurality of electrodes disposed on the top surface;
facing the second surface of the post-like metal material to the top surface of the printed circuit board and electrically connecting one end of the conductor to the corresponding electrode;
providing at least one light-emitting diode including electrodes, and attaching the light-emitting diode to the post-like metal material;
providing a plurality of wires, wherein one end of each wire is electrically connected to the corresponding electrode of the light-emitting diode, and the other end of the conductor is electrically connected with the corresponding wire; and
providing an encapsulating material for covering the first surface of the post-like metal material.

28. The manufacturing method according to claim 27, further comprising providing phosphors around the light-emitting diodes or doping phosphors into the encapsulating material.
